(19) United States
(12) Patent Application Publication
(10) Pub. No.: US 2006/0138941 A1
(43) Pub. Date: Jun. 29, 2006

(54) Electrolumenscent organic light emitting device and production method thereof

(75) Inventor: Georg Wittmann, Herzogenaurach (DE)

Correspondence Address: COHEN, PONTANI, LIEBERMAN & PAVANE;Suite 1210, 551 Fifth Avenue, New York, NY, 10176, US

(73) Assignee: Osram Opto Semiconductors GmbH, Regensburg (DE)

(21) Appl. No.: 11/141,663

(22) Filed: May 31, 2005

Related U.S. Application Data
(60) Provisional application No. 60/639,373, filed on Dec. 27, 2004.

(51) Int. Cl. H01J 5/16

(52) U.S. Cl. 313/504; 313/112

(57) ABSTRACT

An electroluminescent organic device with an electromagnetic radiation emitting front side and having at least one pixel divided into at least two sub-pixels for emitting light with respectively different colors is disclosed. The device comprises a substrate; a first electrode over the substrate; at least one active organic layer over said first electrode for emitting electromagnetic radiation; a second electrode over said active organic layer, said second electrode being at least partially transparent to the electromagnetic radiation emitted by said at least one active organic layer; and a support carrying different kinds of pigments respectively aligned with the sub-pixels of the electroluminescent organic device, said support being arranged over said second electrode toward the radiation emitting front side of the device. Instead of a support with pigments a support with color changing media can be used. Furthermore, a method is disclosed to produce such a device.

### RELATED APPLICATION

This patent application claims the priority of U.S. provisional patent application Ser. No. 60/639,373, filed Dec. 27, 2004, the disclosure content of which is hereby incorporated by reference.

### FIELD OF THE INVENTION

The invention relates to a multi-colored electroluminescent organic light emitting device and a method for fabrication thereof.

### BACKGROUND OF THE INVENTION

U.S. Pat. No. 6,133,692 describes a white light generating electroluminescent device with an organic light emitting diode. The organic light emitting diode comprises a transparent substrate carrying active organic material sandwiched between two electrodes. During operation of the device, the active organic material emits light with a broad band spectrum containing a component of each primary color. The generated light is radiated through the first electrode and through the substrate (bottom-emitter). In order to balance the primary color components, color filters are arranged between the substrate and the first electrode. Therefore, the color filters are applied to the substrate and then the rest of the device is formed on the same substrate. This has the disadvantage that if a process step occurring after fabrication of the color filters on the substrate fails, the whole device together with the expensive color filters has to be discarded.

### SUMMARY OF THE INVENTION

One object of the invention is to provide an improved electroluminescent organic device, particularly a full color display comprising red, green and blue sub-pixels based on organic light emitting diodes (OLED-display), and an improved method for the production thereof.

An electroluminescent organic device with an electromagnetic radiation emitting front side and having at least one pixel divided into at least two sub-pixels for emitting light with respectively different colors, comprises:

a substrate;

a first electrode over the substrate;

at least one active organic layer over said first electrode for emitting electromagnetic radiation;

a second electrode over said active organic layer, said second electrode being at least partially transparent to the electromagnetic radiation emitted by said at least one active organic layer; and

a support carrying different kinds of pigments respectively aligned with the sub-pixels of the electroluminescent organic device, said support being arranged over said second electrode toward the radiation emitting front side of the device.

In one embodiment of the invention, the active organic layer comprises active organic material emitting electromagnetic radiation with a broad band spectrum generating light with a white color impression. The active organic material sandwiched between two electrodes is arranged on a substrate. The broad band radiation produced within the active organic layer is emitted through the second electrode (top-emitter) and passes through the pigments generating the desired color impression.

To achieve an enhanced radiation efficiency of the device the first electrode is preferably reflective for the radiation emitted by the device. A reflective electrode comprises for example a metallic layer with good reflective properties, such as an layer comprising at least one material of the group formed by Ag, Al, Mg, Ca and Pt or an alloy of two or more of these metals.

On the support, such as the color filter plate, layers with different kinds of pigments are deposited in regions corresponding to the sub-pixels. Each kind of pigment transmits radiation with a different spectral range from the broad band spectrum, while the rest of the radiation is absorbed by the pigments. Therefore, every kind of pigment generates sub-pixels with different color.

A color filter plate out of glass as well as plastic foils or plates at least partially transparent for the radiation emitted by the electroluminescent organic device can be used as support for the different pigments.

In the following description, “full color” means the region of the CIE-chromaticity diagram, which is spanned by the three color vectors red, green and blue. In order to produce a full colored electroluminescent organic device, each pixel comprises preferably at least one red, one green and one blue sub-pixel and consequently the color filter plate provides separated regions with red, green and blue pigments generating these colors located corresponding to the sub-pixels.

Since the support carrying the pigments is placed over the second electrode toward the front-side of a top-emitter, the support carrying the pigments can be processed independently from the other functional parts of the device, such as electrodes and active organic layer. In contrast to the bottom-emitter, where the radiation generated within the active organic material is emitted through the substrate and therefore the pigments on the support are arranged below the sandwich-structure of electrodes and active organic material on the same substrate, the above described arrangement decouples the fabrication of the support with the pigments from the fabrication of the rest of the device. This has the advantage that the expensive support with the pigments plate will not have to be discarded, if the processing of other functional parts of the device fails, as in the case of a bottom-emitter. Furthermore, the fabrication processes of the rest of the device, particularly of the sandwiched structure comprising active organic material and electrodes, do not have to be compatible with the support an the pigments thereon. Also, the pigments and the processes used for the fabrication of support with the pigments can be optimized independently from the rest of the device.

In one embodiment of the invention, the support is a color filter plate carrying the different kind of pigments.

Preferably, the color filter plate encapsulates the device. Since the pigments forming the color generating areas of the color filter plate can be deposited on a very thin glass plate, a color filter plate represents a lightweight encapsulation substrate.

In one embodiment of the invention, the first and the second electrodes have a stripe-wise form running perpendicular to each other. The area where a first electrode crosses a second electrode defines a pixel or a sub-pixel, and by applying a voltage to the electrodes the pixel or sub-pixel can be addressed.

In one embodiment of the invention, thin film transistors (TFT) are arranged between the substrate and the first electrode, controlling pixels and sub-pixels. In particular, active matrix displays comprise TFTs for controlling single sub-pixels. The controlling of pixels and sub-pixels by means of TFTs reduces the driving voltage of the device and makes it possible to produce larger pixelated device areas than by means of crossed stripe-shaped electrodes.

The fabrication of TFTs between the substrate and the first electrode requires further costly and time-consuming process steps. Therefore, if TFTs are intended to control the sub-pixel, it is particularly favorable to decouple the processing of the TFTs and the sandwiched structure of electrodes and active material from the processing of the color filter plate.

Instead of a support with different kinds of pigments according to the sub-pixels, a support with color changing media (CCM) can be used. In contrast to pigments, which absorb the unwanted spectral part of incident electromagnetic radiation, CCMs are excited by a spectral part of the incident electromagnetic radiation and reemit electromagnetic radiation with other wavelengths, mostly with longer wavelengths. Therefore, by applying the same voltage to an organic electroluminescent device higher radiation intensities can be achieved by means of CCMs for color generation than by means of pigments. As in the case of pigments, the CCMs are deposited on a support in regions corresponding to the sub-pixels.

For the realization of a full color electroluminescent organic device, where every pixel comprises at least one red, one green and one blue sub-pixel, preferably blue-emitting active organic material, such as spirobifluorene, is used in connection with CCMs. To create blue sub-pixels, the corresponding regions of the support have to be at least partially transparent for the blue light emitted by the active organic material. Red and green sub-pixels are created by depositing suitable color-changing media in the regions of the plate respectively corresponding to the red and green sub-pixels.

A method for producing an electroluminescent organic device with an electromagnetic radiation emitting front side and having at least one pixel divided into at least two sub-pixels for emitting light with respectively different colors, comprises the steps:

providing a substrate;

depositing a first electrode over the substrate;

depositing at least one active organic layer over said first electrode for emitting electromagnetic radiation;

depositing a second electrode over said active organic layer, said second electrode being at least partially transparent to the electromagnetic radiation emitted by said at least one active organic layer; and

arranging a support carrying different kinds of pigments respectively aligned with the sub-pixels of the electroluminescent organic device over said second electrode toward the radiation emitting front side of the device.

Preferably, a plate is used as support and this plate encapsulates the device.

Instead of a support with pigments, a support with color changing media as described above can be used.

In one embodiment of the invention, the plate with the color-generating materials (pigments or CCM) is arranged in direct contact to the second electrode to ensure that as much radiation as possible emitted by the active organic material incidents on the corresponding color-generating field on the plate. Furthermore, the encapsulation of the device by the plate is enhanced in this case. The plate can also be bonded to the second electrode with an adhesive layer.

In a further embodiment of the invention, the plate is mounted on a substrate at a distance to the second electrode to avoid damage of the functional parts of the device, such as electrode layers or active organic layers. In order to ensure a distance between the plate and the second electrode spacers, particularly spacer particles, can be used. Alternatively or additionally rims or supports posts within the pixelated region of the device can be used as spacers. It is further possible to use bank structures as spacers, which can be deposited on the substrate for electrode patterning and definition of pixel and sub-pixel areas particularly in passive matrix devices.

In the following, the invention is described in further detail on the basis of different embodiments in conjunction with the drawings.

### BRIEF DESCRIPTION OF THE DRAWINGS

FIGS. 1A to 1D show schematic cross-sectional views of an OLED-device according to one embodiment of the invention at different fabrication steps.

FIG. 1E shows a detail of FIG. 1D.

FIGS. 2, 3 and 4 show schematic cross-sectional views of OLED-devices according to different embodiments of the invention.

FIGS. 5A to 5D show further schematic cross-sectional views of an OLED-device at different fabrication steps according to an embodiment of the invention.

FIG. 6 schematically shows the patterning of first and second electrode strips forming a matrix of addressable pixels and sub-pixels according to an embodiment of the invention.

FIG. 7 schematically shows TFT switching elements arranged between the substrate and the first electrode to address single pixels and sub-pixels.

### DETAILED DESCRIPTION OF THE DRAWINGS

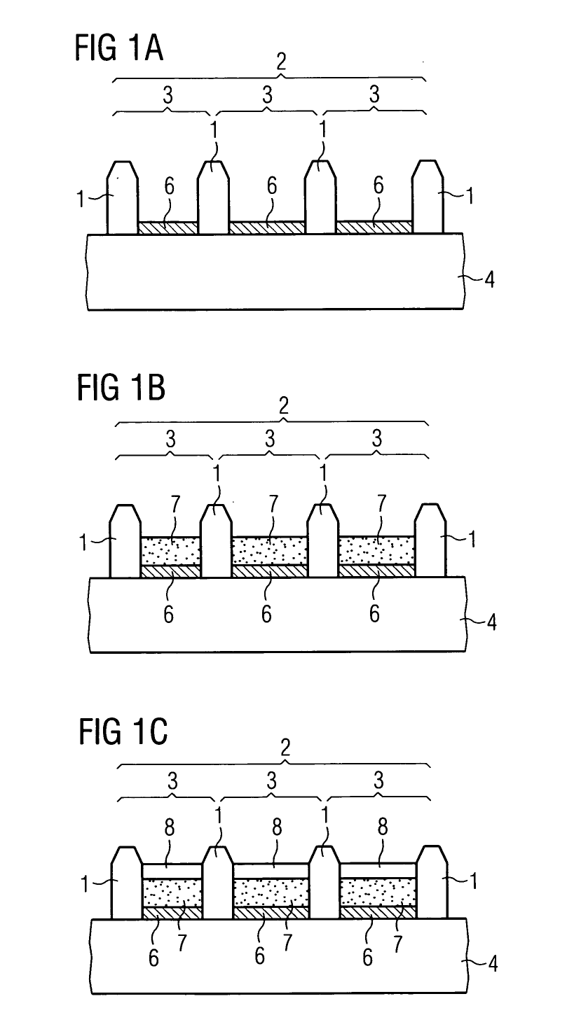

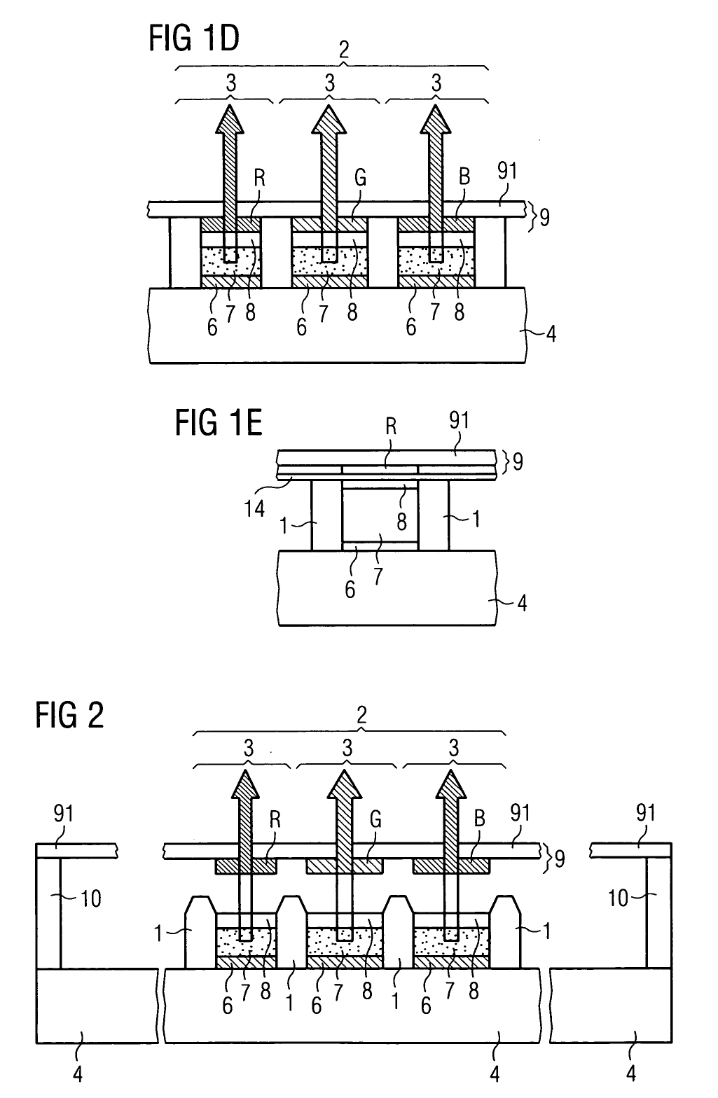

In accordance with one embodiment of the invention, FIGS. 1A to 1D show cross-sectional views of an OLED-device at different process steps. In order to produce a full-color OLED-device, electrically insulating bank structures 1 are deposited on a substrate 4 to define pixel 2 and sub-pixel areas 3, as depicted in FIG. 1A. The pixel 2, and the respective sub-pixel areas 3, can have the form of pockets, which are separated from each other by the bank structures 1. The electrically insulating bank structure 1 can be made of photoresist patterned by lithographic or printing techniques, such as screen printing or flexo-printing. The bank structure 1 can have, for example, a trapezoidal configuration in which the angle between the side wall of the bank structure 1 and the first electrode 6 is an obtuse angle. Alternatively, the bank structure 1 can be semicircular or curved in nature.

In contrast to a bottom emitter, which requires a transparent substrate 4, an opaque substrate 4 can be used. The following materials are suitable as constituents of substrate 4: glass, semiconductor materials, such as silicon, metal foils, such as steel or stainless steel foils, or plastic materials, such as poly(ethylene terephthalate) (PET), poly(butylene terephthalate) (PBT), poly(enthylene naphthalate) (PEN), polycarbonate (PC), polyimides (PI), polysulfones (PSO), poly(p-phenylene ether sulfone) (PES), polyethylene (PE), polypropylene (PP), poly(vinyl chloride) (PVC), polystyrene (PS) and poly(methyl methyleacrylate) (PMMA), are suited for example.

Preferably, the substrate is very thin. Furthermore, any kind of foil, for example of the above-mentioned materials, is particularly suited for the realization of light weight and/or flexible devices.

A first electrode 6, comprising one or more electrode layers, is deposited on the substrate 4. The first electrode 6 can serve as an anode or as a cathode. If the first electrode 6 serves as an anode, it comprises a material with a high work function for electrons, such as Indium-Tin-Oxide (ITO) LiF or Pt. If the first electrode 6 serves as a cathode, it comprises a material with a low work function for electrons, such as Ca or Mg. Since the finished OLED-device emits radiation directed toward the top and not downward through the substrate 4, the first electrode has preferably reflective properties for the radiation emitted by the device. Therefore, if the first electrode 6 comprises a layer transparent for the radiation emitted by the device, such as ITO, the first electrode 6 preferably comprises one or more additional reflective layers, such as a 4 to 5 nm thick Al-layer or Ag-layer. The first electrode 6 can furthermore comprise one or more electrode layers, which enhance carrier injection into the active organic material 7 or conductivity of the electrode 6.

Subsequent to the first electrode 6, one or more active organic layers 7 are deposited over the first electrode 6 as shown in FIG. 1B. The active organic layers 7 comprise at least one emitting layer comprising emitter material. According to the first embodiment of the invention the active organic material 7 is a white broadband emitter suited to generate electromagnetic radiation with a broad spectral range producing a white color impression. A white broadband emitter can be based on small molecules deposited by evaporation in vacuum, polymer blends doped with fluorescent dyes or polymeric material comprising copolymers. Such copolymers can be built up of a blue-emitting backbone of polyspirobifluorenen with covalently coupled red- and green-emitting structural elements. Such a broad band emitter based on copolymers is for example described in further detail in document D. Buchhauser et al., “Characterization of White-Emitting Copolymers for PLED-Displays”, Proc. of SPIE”, Vol. 5519, pp. 70-81, (2004), which is hereby incorporated by reference for all purposes in its entirety. Polymeric materials can be deposited by solution-based processes like spin-coating, doctor-blading or printing techniques, such as flexo-printing or screen printing.

Besides the active organic emitter material 7 of the emitter layer, the active organic layers can comprise one or more electron-transporting layers or one or more hole-transporting layers. The electron-transporting layer is preferably positioned adjacent to the cathode and the hole-injection layer is preferably positioned adjacent to the anode.

Referring to FIG. 1C a second electrode 8 is deposited in a subsequent step over the active organic material 7. The second electrode 8 can serve as a cathode or as an anode. If the first electrode 6 acts as a cathode, the second electrode 8 acts as anode and vice versa. Equivalently, as described above in context with the first electrode 6, the second electrode 8 comprises an electrode layer with a high-work function material, if the second electrode 8 acts as an anode, such as ITO, LiF or Pt. If the second electrode 8 acts as a cathode, it comprises a low-work-function material, such as Ca or Mg. Since the radiation emitted by the active organic material 7 has to pass through the second electrode 8, it has to be at least partially transparent for this radiation. Therefore, materials with a non-negligible absorption-coefficient for the radiation emitted by the device, such as Ca, Mg or Pt, are deposited in such a thin layer that the second electrode 8 is at least semi-transparent for the radiation of the device. An electron injection cathode can comprise for example a Ca-layer with a thickness of 2-3 nm, which is semi-transparent for the radiation of the device.

As depicted in FIG. 1D, the OLED-device is encapsulated by a color filter plate 9 in a subsequent step. The color filter plate 9 comprises a support 91, for example a thin lightweight glass plate, with separated color generating regions containing pigments R, G, B which generate the desired color impression of the corresponding sub-pixel. For a full color OLED-display, one pixel is divided into one red sub-pixel, one green sub-pixel and one blue sub-pixel, and the color generating areas comprise the pigments R, G, B accordingly. The pigments R, G, B, which can be mixed with polyacrylates, can be deposited by solution-based processes and photolithographic techniques.

Thin foils or plates out of plastic material, which is at least partially transparent for the radiation emitted by the electroluminescent organic device, can also be used as support 91 for the pigments R, G, B.

The color filter plate is mounted over the second electrode 8 toward the front side of the substrate, 4, in such a way that the color-generating regions of the color filter plate 9 are positioned in alignment corresponding to the sub-pixels. As depicted in FIGS. 1D and 1E, the color filter plate 9 can be mounted in direct contact with the second electrode 8, for example by using an additional adhesive layer 14 applied between the second electrode 8 and the color filter plate 9.

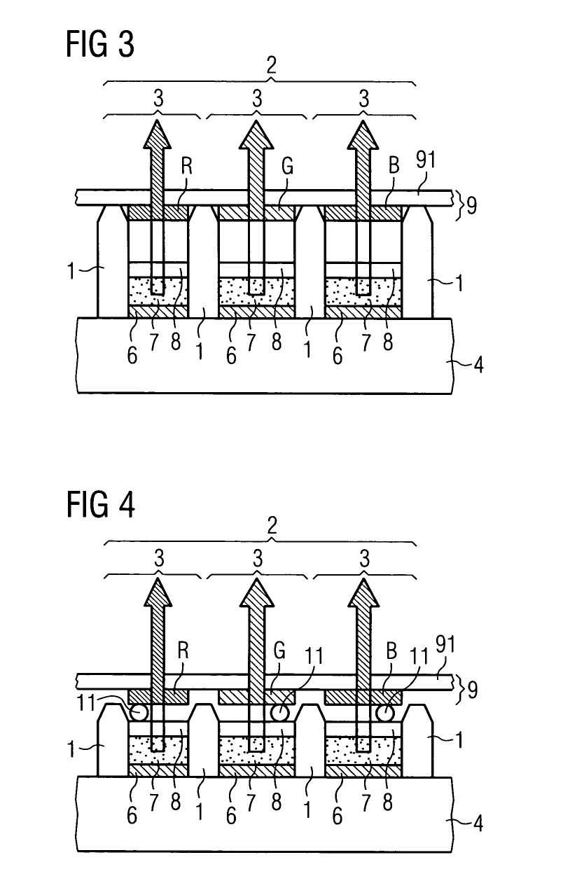

Alternatively, the color filter plate 9 is mounted at a distance from the second electrode 8, as depicted in FIGS. 2, 3 and 4. To create the distance between the second electrode 8 and the color filter plate 9, support posts 10 or a support rim 10 can be positioned outside the pixelated active region of the OLED-device (FIG. 2). Furthermore, the pixelated active region of the OLED-device can alternatively or additionally comprise spacers. The bank structures 1 (FIG. 3) or spacer particles 11 (FIG. 4) can serve as spacers. Spacer particles 11 and their use for encapsulation of OLED-devices are, for example, described in documents WO 01/45140 and WO 01/44865, which are incorporated herein by reference for all purposes in their entirety.

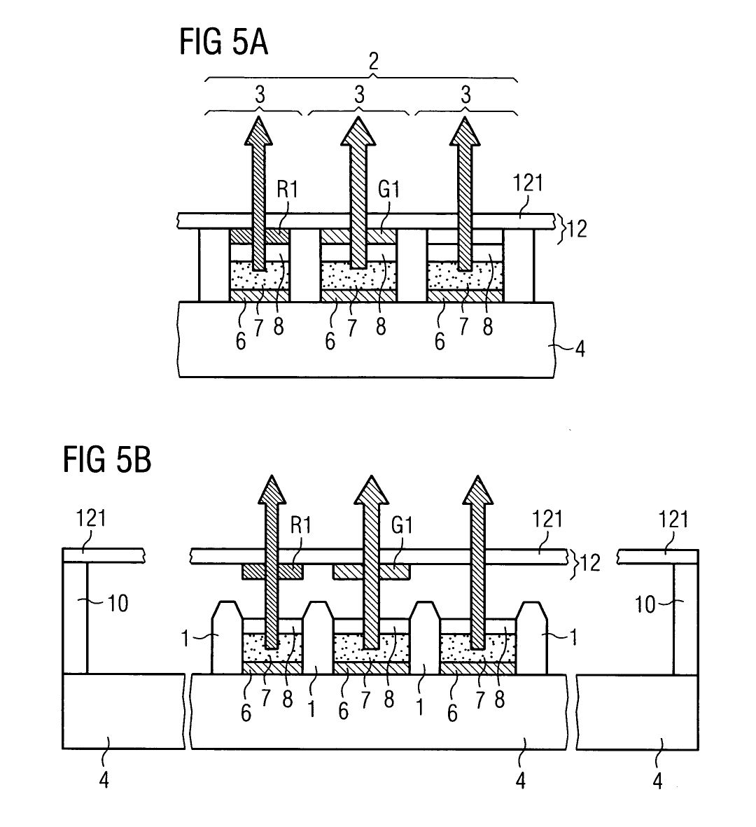

According to the embodiment of the invention depicted in the FIGS. 5A to 5D, a plate with color-changing media 12 (CCM) is used instead of a color filter plate 9. As color-changing media, R1, G1 color-conversion material can be used. Such color-conversion material is for example described in document U.S. Pat. No. 6,066,861, which is herein incorporated by reference for all purposes in its entirety. The further parts of the OLED-device can be processed as described above in detail in connection with the FIGS. 1A to 1C, with the exception of the active organic emitter material. Since the color-changing media R1, G1 converts incident light into light with a longer wavelength, blue emitter material is deposited over the first electrode 6 instead of a white emitting broad band material. As blue emitter material polyspirobifluorenen or polyfluorene can be used, for example.

In order to produce a full color display with pixels comprising one red, one green and one blue sub-pixel, CCMs R1 which convert incident blue light into red light are placed on a thin transparent plate 121 such as a thin glass plate, in regions corresponding to the red sub-pixels, while CCMs G1 which convert incident blue light into green light are placed on the plate 121 in regions corresponding to the green sub-pixels. To achieve blue sub-pixels no CCM is required, but the regions of the plate 121 corresponding to the blue sub-pixels have to transmit blue light emitted by the active organic material 7.

The plate with structured CCM layers R1, G1, is mounted over the second electrode 8 to encapsulate the OLED-device. As in the case of a color filter plate 9, the CCM plate 12 can be mounted in direct contact with the second electrode 8 (FIG. 5A) or at a distance to the second electrode 8 (FIGS. 5B to 5D). To create the distance between the CCM plate 12 and the second electrode 8, spacers 10 outside the pixelated area of the display can be used as described above in connection with the mounting of the color filter plate 9. Additionally or alternatively, spacers such as the bank structures 1 or spacer particles 11 can be placed within the pixelated region of the OLED-device.

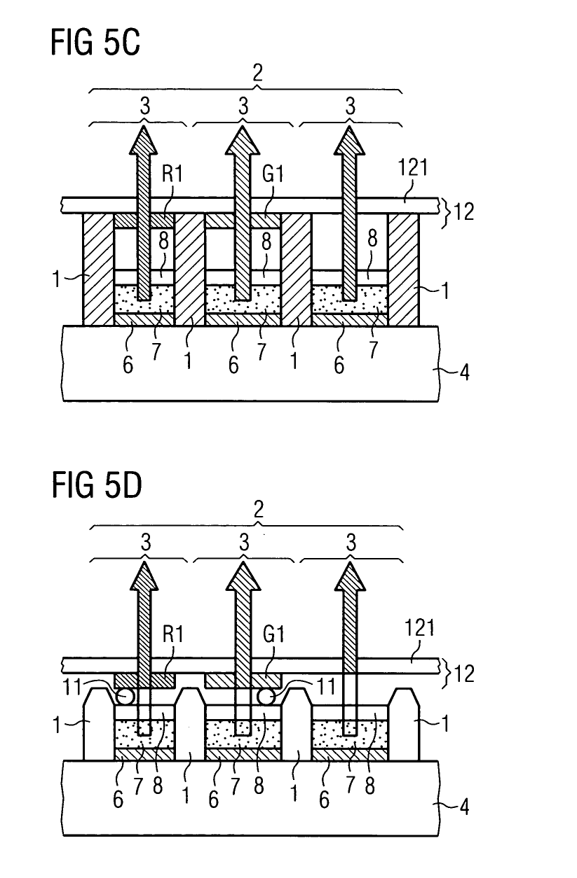

To form a pixel matrix of an OLED-display with single addressable pixels and sub-pixels, the first and the second electrode 6, 8 can be patterned in strips running perpendicular to each other, as shown in FIG. 6. For the patterning of the second electrode 8, pillars, preferably with an overhanging structure, can be used. The patterning of electrodes is described in documents U.S. Pat. No. 6,699,728, U.S. Pat. No. 6,696,312 and U.S. Pat. No. 6,784,009, which are herein incorporated by reference for all purposes in their entirety.

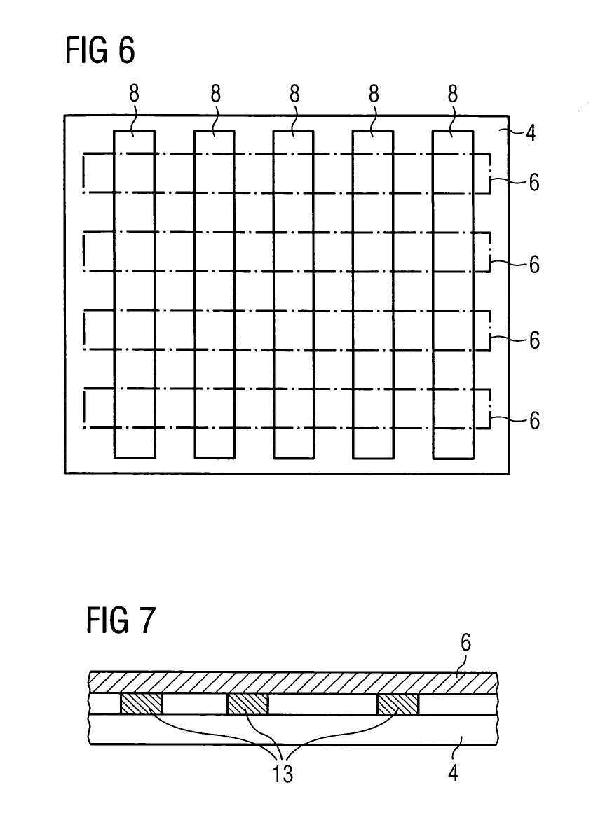

Furthermore, TFT-switching elements 13 can be arranged between the substrate 4 and the first electrode 6 to address single pixels or sub-pixels, as shown in FIG. 7. The integration of TFTs 13 and organic LEDs is for example described in C. C. Wu et al., “Integration of Organic LED's and Amorphous Si TFT's onto Flexible and Lightweight Metal Foils Substrates”, IEEE Electronic device letters, Vol. 18, 12, pp. 609-612, (1997), which is herein incorporated by reference for all purposes in its entirety.

If the pixels and sub-pixels are addressed by TFT-switching elements 13, it is not necessary to deposit the bank structures 1 on the substrate in order to define pixel and sub-pixel regions 2, 3, since they are defined by the TFT-switching elements 13.

The scope of the invention is not limited to the examples given hereinabove. The invention is embodied in each novel characteristic and each combination of characteristics, which particularly includes any combination of the features which are described in the claims, even if this feature or this combination of features is not explicitly referred to in the claims or in the examples.

We claim:

1. An electroluminescent organic device with an electromagnetic radiation emitting front side and having at least one pixel divided into at least two sub-pixels for emitting light with respectively different colors, the device comprising:
a substrate;
a first electrode over the substrate;
at least one active organic layer over said first electrode for emitting electromagnetic radiation;
a second electrode over said active organic layer, said second electrode being at least partially transparent to the electromagnetic radiation emitted by said at least one active organic layer; and
a support carrying different kinds of pigments respectively aligned with the sub-pixels of the electroluminescent organic device, said support being arranged over said second electrode toward the radiation emitting front side of the device.

2. The device of claim 1, wherein said support is a color filter plate.

3. The device of claim 2, wherein said color filter plate encapsulates the device.

4. The device of claim 2, wherein the color filter plate is arranged in direct contact to the second electrode.

5. The device of claim 2, wherein the color filter plate is bonded to the second electrode by an adhesive layer.

6. The device of claim 2, wherein the color filter plate is mounted at a distance to the second electrode.

7. The device of claim 6, wherein the color filter plate is mounted on the substrate at a distance to the second electrode by means of spacers.

8. The device of claim 7, wherein the spacers are spacer particles.

9. The device of claim 1, wherein thin film transistors (TFT) are arranged between the substrate and the first electrode corresponding to the sub-pixels.

10. The device of claim 1, wherein the active organic layer comprises white light emitting organic material.

11. The device of claim 1, wherein the first electrode reflects the radiation emitted by the active organic layer.

12. The device of claim 1, wherein each pixel includes at least one red, one green and one blue sub-pixel.

13. An electroluminescent organic device with an electromagnetic radiation emitting front side and having at least one pixel divided into at least two sub-pixels for emitting light with respectively different colors, the device comprising:
a substrate;
a first electrode over the substrate;
at least one active organic layer over said first electrode for emitting electromagnetic radiation;
a second electrode over said active organic layer, said second electrode being at least partially transparent to the electromagnetic radiation emitted by said at least one active organic layer; and
a support carrying different kinds of color changing media (CCM) respectively aligned with the sub-pixels of the electroluminescent organic device, said support being arranged over said second electrode toward the radiation emitting front side of the device.

14. The device of claim 13, wherein said support is a plate.

15. The device of claim 14, wherein said plate encapsulates the device.

16. The device of claim 14, wherein the plate is arranged in direct contact to the second electrode.

17. The device of claim 14, wherein the plate is bonded to the second electrode by an adhesive layer.

18. The device of claim 14, wherein the plate is mounted on the substrate at a distance to the second electrode.

19. The device of claim 18, wherein the plate is mounted to the substrate at a distance to the second electrode by means of spacers.

20. The device of claim 19, wherein the spacers are spacer particles.

21. The device of claim 13, wherein thin film transistors are arranged between the substrate and the first electrode corresponding to the sub-pixels.

22. The device of claim 13, wherein the active organic layer comprises blue light emitting organic material.

23. The device of claim 13, wherein the first electrode reflects the radiation emitted by the active organic layer.

24. The device of claim 13, wherein each pixel includes at least one red, one green and one blue sub-pixel.

25. A method for producing an electroluminescent organic device with an electromagnetic radiation emitting front side and having at least one pixel divided into at least two sub-pixels for emitting light with respectively different colors, comprising the steps:
providing a substrate;
depositing a first electrode over the substrate;
depositing at least one active organic layer over said first electrode for emitting electromagnetic radiation;
depositing a second electrode over said active organic layer, said second electrode being at least partially transparent to the electromagnetic radiation emitted by said at least one active organic layer; and
arranging a support carrying different kinds of pigments respectively aligned with the sub-pixels of the electroluminescent organic device over said second electrode toward the radiation emitting front side of the device.

26. The method of claim 25, wherein said support is a color filter plate.

27. The method of claim 26, wherein said color filter plate encapsulates the device.

28. The method of claim 26, wherein the color filter plate is arranged in direct contact to the second electrode.

29. The method of claim 26, wherein the color filter plate is bonded to the second electrode by an adhesive layer.

30. The method of claim 26, wherein the color filter plate is mounted to the substrate at a distance to the second electrode.

31. The method of claim 26, wherein the color filter plate is mounted to the substrate at a distance to the second electrode by means of spacers.

32. The method of claim 31, wherein the spacers are spacer particles.

33. The method of claim 25, wherein thin film transistors are arranged between the substrate and the first electrode layer corresponding to the sub-pixels.

34. The method of claim 25, wherein the active organic layer comprises white light emitting organic material.

35. The method of claim 25, wherein the first electrode comprises a material reflecting the radiation emitted by the active organic layer.

36. The method of claim 25, wherein each pixel is divided in one red, one green and one blue sub-pixel.

37. A method for producing an electroluminescent organic device with an electromagnetic radiation emitting front side and having at least one pixel divided into at least two sub-pixels for emitting light with respectively different colors, comprising the steps:
providing a substrate;
depositing a first electrode over the substrate;
depositing at least one active organic layer over said first electrode for emitting electromagnetic radiation;
depositing a second electrode over said active organic layer, said second electrode being at least partially transparent to the electromagnetic radiation emitted by said at least one active organic layer; and
arranging a support carrying different kinds of color changing media (CCM) respectively aligned with the sub-pixels of the electroluminescent organic device over said second electrode toward the radiation emitting front side of the device.

38. The method of claim 37, wherein said support is a plate.

39. The method of claim 38, wherein said plate encapsulates the device.

40. The method of claim 38, wherein the plate is arranged in direct contact to the second electrode.

41. The method of claim 38, wherein the plate is bonded to the second electrode by an adhesive layer.

42. The method of claim 38, wherein the plate is mounted to the substrate at a distance to the second electrode.

43. The method of claim 42, wherein the plate is mounted to the substrate at a distance to the second electrode by means of spacers.

44. The method of claim 43, wherein the spacers are spacer particles.

45. The method of claim 37, wherein thin film transistors are arranged between the substrate and the first electrode layer corresponding to the sub-pixels.

46. The method of claim 37, wherein the active organic layer comprises blue light emitting organic material.

46. The method of claim 37, wherein the first electrode comprises a material reflecting the radiation emitted by the active organic layer.

47. The method of claim 37, wherein each pixel is divided in one red, one green and one blue sub-pixel.
